(19) United States
(12) Patent Application Publication
(10) Pub. No.: US 2003/0021390 A1
(43) Pub. Date: Jan. 30, 2003

(54) Device for connection of a device on a telephone line

(76) Inventors: Dominique Delbecq, Caen (FR); Fernand Courtois, Saint Contest (FR)

Correspondence Address: Steven R Biren, US Philips Corporation, Intellectual Property Department, 580 White Plains Road, Tarrytown, NY, 10591, US

(21) Appl. No.: 10/204,656

(22) PCT Filed: Dec. 19, 2001
(86) PCT No.: PCT/IB01/02663

(30) Foreign Application Priority Data
Dec. 28, 2000 (FR) 00/17203

(51) Int. Cl. H04M 1/24; H04M 3/08; H04M 3/22; G01R 31/08; G01R 31/28

(52) U.S. Cl. 379/22.01; 324/527; 324/528

(57) ABSTRACT

The present invention relates to a device for connection of a digital apparatus on a telephone line, comprising a line interface (6) which is connected to the telephone line, and a control circuit (8) to control this line interface (6), which can detect a fault in transmission through the line, the line interface (6) and the control circuit (8) each comprising at least one memory (42, 44, 62,64), and exchanging digital information via a galvanic connection.

According to the invention, the communication between the line interface (6) and the control circuit (8) is produced according to a protocol during which:

the control circuit (8) transmits continuously, and in a loop, to the line interface (6), a first data packet (TX) which is provided with a first address, and receives in return from the line interface (6) a second digital data packet (RX), which is provided with a second address; and

the control circuit (8) detects a transmission fault on the line, if the first and second addresses are different.

The invention is applied in the field of transmissions by means of a telephone line, and relates more particularly to a device for connection of an apparatus on a telephone line, comprising a line interface which is connected to the telephone line, and a control circuit to control this line interface, which can detect a fault in transmission through the line, the line interface and the control circuit each comprising at least one memory, and being designed to exchange information via a galvanic connection.

The invention also relates to a method for detection of faults in a connection between an apparatus and a telephone line.

An increasing number of apparatus (computers, modems, fax machines etc) are exchanging data by means of a telephone line. In order to prevent major disturbances which occur on the line from affecting the operation of these apparatus, the latter are connected to the line via a galvanic barrier, by means of which binary emission TX and reception RX frames are transmitted, with control data of a line interface and state data indicating the operative state of the line. The line interface receives a supply voltage from the galvanic barrier side which comprises the digital apparatus.

The galvanic barrier can be produced from high-voltage capacitors, owing to the low cost of the latter. A galvanic isolation device of this type is described in international patent application WO 98/48541.

A problem which is associated with this type of isolation is derived from the fact that, when power is not being supplied to the line interface, i.e. before a connection is started up, the line interface does not receive any supply from the telephone line.

An object of the invention is to provide a device which can transmit control information, and receive state information, without errors, whilst monitoring continually the state of the line interface, in order to detect communication which is excessively disrupted, or a cut-off of communication, irrespective of the state of this interface.

According to the invention, this object is achieved by means of a device in which communication between the line interface and the control circuit takes place according to a protocol during which:

the control circuit transmits continuously, and in a loop, to the line interface, a first data packet which is provided with a first address, and receives in return from the line interface a second data packet, which is provided with a second address; and

the control circuit detects a transmission fault on the line, if the first and second addresses are different.

According to an embodiment of the invention, the first and second data packets comprise respectively the content of a control register and of a state register, and a memory address associated with each register, the first data packet additionally comprising a synchronization key.

According to a particular embodiment of the invention, the line interface can detect the synchronization key, decode the memory address of each register, and return the content of the state register, provided with the same address, into the memory of the control circuit.

According to an advantageous embodiment of the invention, the data contained in each control register, as well as the data contained in each state register, are validated by an error detector code CRC.

The device according to the invention makes it possible to implement a method for detection of faults in a connection between an apparatus and a telephone line, by means of a line interface controlled by a control circuit. The invention thus also relates to a method for detection of errors, comprising the following steps:

the control circuit transmits continuously, and in a loop, to the line interface, a first data packet which is provided with a first address, and receives in return from the line interface a second data packet, which is provided with a second address; and

the control circuit detects a transmission fault on the line, if the first and second addresses are different.

These and other aspects of the invention are apparent from and will be elucidated, by way of non-limiting example, with reference to the embodiment(s) described hereafter.

In the drawings:

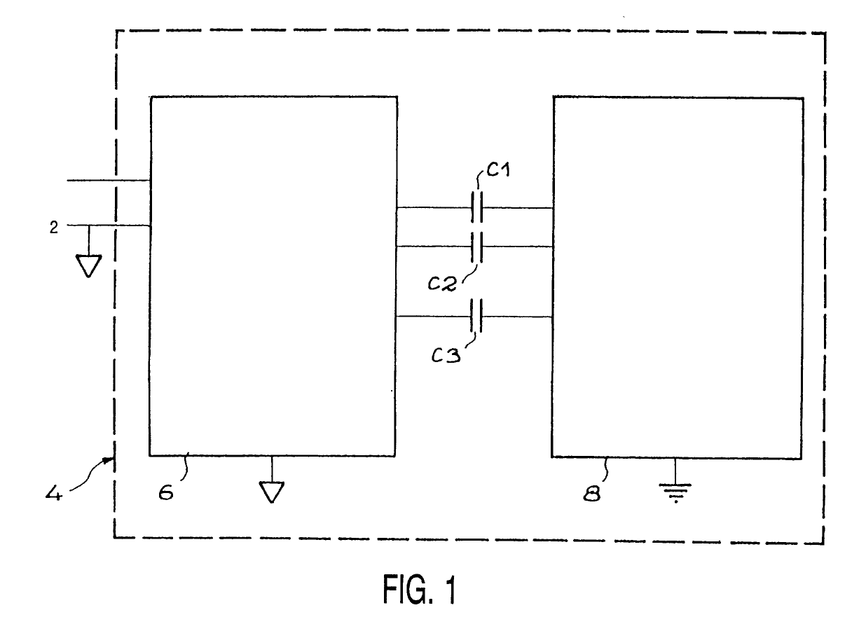

FIG. 1 shows schematically a device according to the invention;

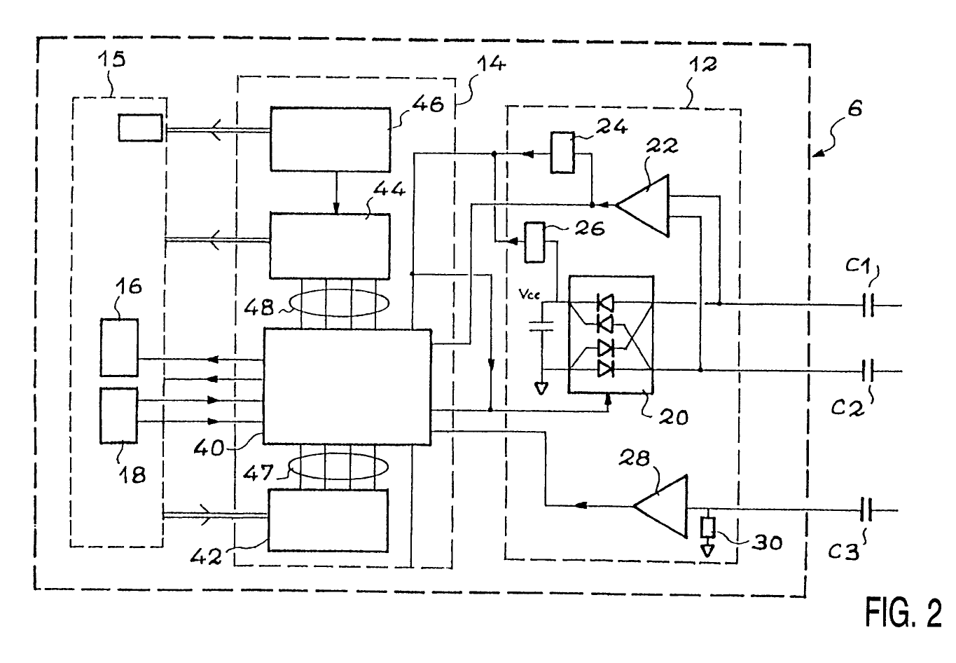

FIG. 2 shows a detailed diagram of a line interface of the device in FIG. 1;

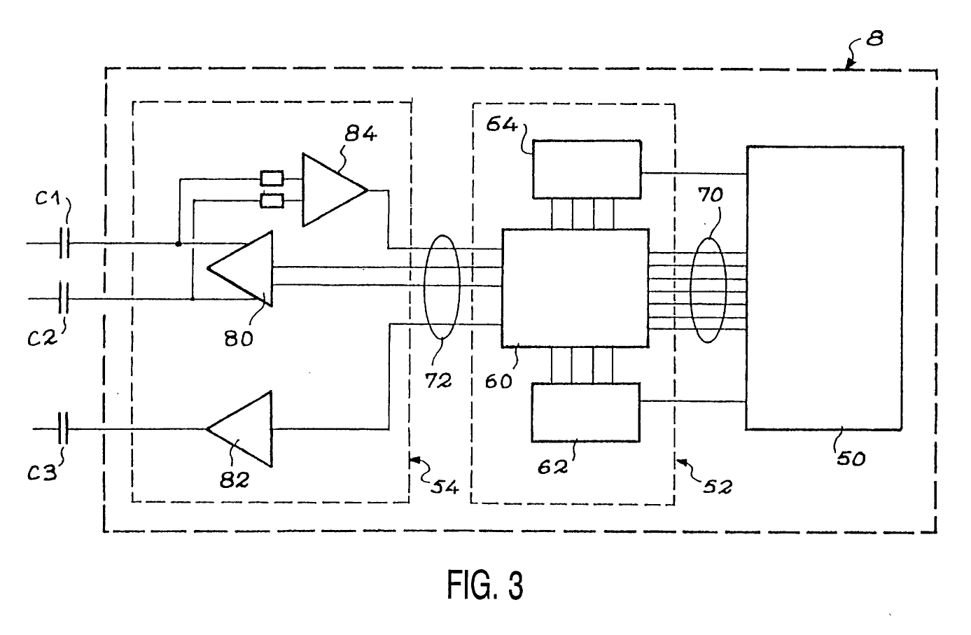

FIG. 3 shows a detailed diagram of a control circuit of the line interface in FIG. 2; and

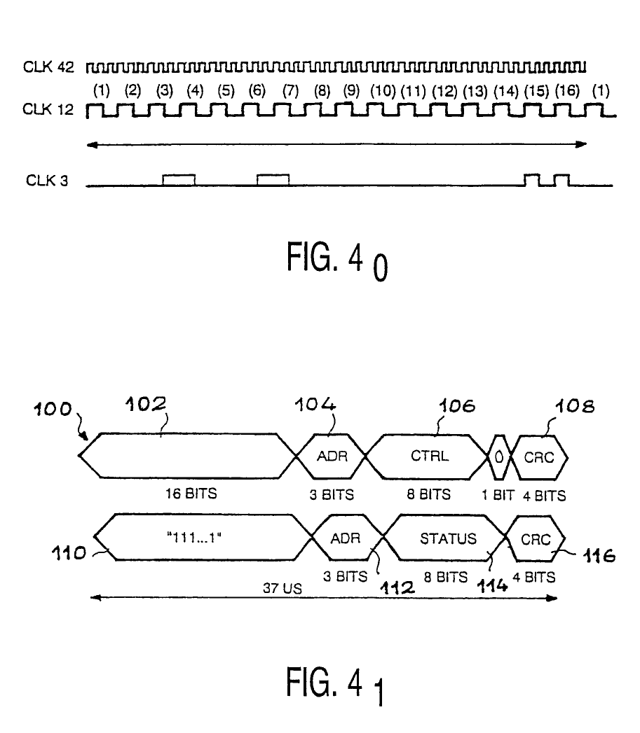

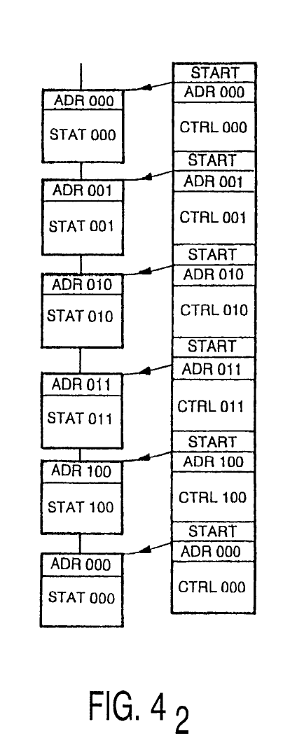

FIG. 4 shows the communication protocol between the line interface in FIG. 2 and the control circuit in FIG. 3.

FIG. 1 shows a device 4 for connection to a telephone line 2, which can be installed on such as a modem. The device 4 comprises a line interface 6 which is connected to an apparatus to the telephone line 2, and a control circuit 8 of the line interface 6. The control circuit 8 and the line interface 6 communicate via a galvanic connection comprising three capacitors C1, C2 and C3.

FIG. 2 shows a detailed diagram of the line interface 6. The latter comprises an input stage 12, which assures the connection between the line interface 6 and the capacitors C1, C2 and C3, a digital block 14 in which there are provided digital components which are used to control the telephone line. This digital block 14 communicates with an analogue block 15, in which a digital-analogue converter 16, and an analogue-digital converter 18 are provided.

The input stage 12 comprises a rectifier bridge 20, which is designed to rectify a clock signal clk12, which is supplied by the control circuit 8, in order to generate a DC supply voltage Vcc for the line interface 6. A comparator 22 is disposed between the capacitors C1 and C2, in order to supply a differential voltage to the digital block 14. The output of the comparator 22 is connected to a clock detection module 24, which is designed to reinitialize the line interface 6, if it detects the lack of signals originating from the capacitors C1 and C2. In the example now described, a switch 26 is provided between the bridge 20 and the digital block 14, in order to deactivate the latter when the differential voltage at the output of the comparator 22 is lower than a predetermined threshold.

The capacitor C3 is connected to a first monitoring amplifier 28, which is designed to store a voltage temporarily at the terminals of a resistor 30, thus making it possible to connect the line interface 6 to ground, when the information supplied to the line interface 6 via the capacitor C3 is not at the logic level “1”.

The digital block 14 comprises a calculation unit 40, a first RAM memory 42 containing five state registers with eight bits, a second RAM memory 44 containing five control registers with eight bits, and a digital line control module 46. The calculation unit 40 is connected to the first RAM memory 42 by a first bus 47, and to the second RAM memory 44 by a second bus 48. The first RAM memory 42 is connected to the analogue block 15, in order to receive logic information which is representative of the state of the telephone line, and the second RAM memory 44 is connected to the analogue block 16, in order to supply control logic information to this block 15.

With reference to FIG. 3, the control circuit 8 comprises a central unit 50, a transmission protocol control stage 52, and an output stage 54, which connects the stage 52 to the capacitors C1, C2 and C3.

The central unit 50 comprises a computer programme, comprising a module which is dedicated to control of the transmission protocol, and a module which is dedicated to processing of the control and state information.

The protocol control stage 52 comprises a calculation unit 60, a third RAM memory 62, comprising five state registers with eight bits, and a fourth RAM memory 64, comprising five control registers with eight bits.

The protocol control stage 52 communicates with the central unit 50 by means of a third bus 70, and with the output stage 54 by means of a fourth bus 72.

The output stage 54 comprises a differential amplifier 80, which is designed to control the voltages applied to the capacitors C1 and C2, a current detector 82, which is designed to measure the differential voltage between the capacitors C1 and C2, and a second monitoring amplifier 84, which is designed to control the voltage of the capacitor C3.

In operation, the control circuit 8 transmits digital data and control data TX to the line interface 6, and receives digital data and state data RX from the line interface 6. The central unit 50 of the control circuit 8 supplies a clock signal clk42. The line interface 6 recuperates this signal by means of the galvanic connection, then supplies a clock signal to the circuits CAN 16 and CNA 18 of the analogue block 15. The exchange of control data and state data between the control circuit and the line interface is controlled by a protocol comprising three levels, i.e. a level 0, a level 1, and a level 2.

The FIG. 4₁ illustrate the signals corresponding to each level.

At the level 0, illustrated by FIG. 4₀, there are represented the signals clk42, and the resulting signals clk12 and ck13, which are generated by the capacitors C1, C2, and C3. At each cycle of the signal clk42, a pair of digital data and control bits TX is transmitted by the control circuit 8 to the line interface 6, and a pair of digital data and state bits RX is transmitted by the line interface 6 to the control circuit 8. During the first fourteen cycles of the signal clk12 (states (1) to (14)), the capacitors C1 and C2 are piloted by the control circuit 8, by means of the differential amplifier 80. During the fifteenth and sixteenth cycles (states (15) and (16)) of the clock signal clk12, the differential amplifier 80 is in a state of high impedance, and the line interface 6 pilots the rectifier bridge 20. The line interface 6 supplies a pair of digital data and state bits RX to the memory 42.

The control circuit 8 applies a sequence of ten consecutive bits “1” to the capacitor C3. These bits are synchronization bits, which are designed to be used by the line interface 6 as a starter key.

At this level of the transmission protocol, the digital data and the control data TX are applied to the capacitor C3.

At the level 1, which is illustrated by FIG. 4₁, the data TX and the data RX are exchanged without control, in the form of specific frames, i.e. a frame TX 100 comprising 32 bits organized in a start word 102, an address with 3 bits 104, a control word with 8 bits 106, and an error detector code CRC TX with four bits 108. The start word is (“0000011111111110”). The error detector code 108 is a cyclical redundancy hamming code, which encodes the control and address words with four bits. This error detector code 108 is capable of detecting at least two incorrect bits in the control and address words. During exchanges of data between the control circuit 8 and the line interface 6, if the error detector code CRC TX 108 is correct, the control word 106 is copied in the second RAM memory 44, which contains the control registers of the line interface 6, at the corresponding address. Thus, the second RAM memory 44 of the line interface 6 will be an image of the fourth RAM memory 64 of the control circuit 8.

A frame TX 100 of this type is transmitted in the following order:

0000011111111110

adr0adr1adr2ctrl0ctrl1ctrl2ctrl3ctrl4ctrl5ctrl6ctrl70crctx3crctx2crctx1crctx0.

The control circuit 8 acts as a master element for communication, whereas the line interface 6 acts as a slave element. The latter detects a word of ten successive bits “1” 110, and transmits, to the same address in the third RAM memory 62 as the address 104 in the frame TX, the corresponding state word 114, followed by an error detector code CRC RX 116.

If the error detector code CRC RX is correct, the state word 110 is copied in the third RAM memory 62 of the control circuit 8, at the same address as the address 104. Thus, the third RAM state memory 62 is an image of the first RAM memory 42 of the state of the line interface 6.

For as long as the line interface 6 has not detected a start word, it transmits information continually, indicating that it is ready to receive.

A frame RX 120 is transmitted in the following order:

1111111111 adr0 adr1 adr2 éta0 éeta1 éta2 éta3 éta4 éta5 éta6 éta7 crcrx3 crcrx2 crcrx1 crcrx0.

FIG. 4₂ illustrates level 2 of the protocol. Before communication starts, the supply voltage Vcc of the line interface 6 can drop, owing to the fact that it is generated by the leading edges of the clock signal clk12. Consequently, in order for the communication protocol to start, it is necessary to maintain the voltage Vcc above a minimum predetermined threshold, by transmitting a synchronization signal on the capacitors C1 and C2.

The protocol is initialized by an ON/OFF command supplied by the central unit 50.

For as long as the line interface 6 is not ready to receive, i.e. for as long as its supply voltage Vcc is lower than the minimum predetermined threshold, the control circuit 8 transmits a specific synchronization frame. This frame is constituted by a succession of bits “0” for the digital data and the control data TX. Consequently, only the synchronization bits are applied to the capacitor C3. The signal clk42 (13.824 Mhz) is applied to the capacitors C1 and C2 during all the cycles except the fourteenth and fifteenth cycles (states (14) and (15) FIG. 4o). In the example now described, for as long as the supply voltage Vcc has not reached the predetermined threshold, the bridge 20 is forced in an analogue manner to supply a logic level “0”, signifying that the line interface is not ready to receive.

When the voltage Vcc reaches the predetermined supply threshold, the switch 26 puts the line interface 6 into active mode. The latter forces the bridge 20 to a logic level “1”, indicating to the control circuit that it is ready to receive, and is waiting for a start word from the control circuit 8. The latter receives continually a bit “1” at the capacitors C1 and C2, and after nine successive bits “1” goes into active mode.

In such a case, the control circuit 8 transmits continually, and in a loop, the content of the control registers, and the line interface 6 responds by transmitting the content of the state registers. At this level, the protocol makes it possible to verify that the communication is correct. This verification is obtained as follows:

the line interface which receives the frame TX verifies that the error detector code CRC TX is correct;

If this is the case, then:

the content of the control register is loaded in the control register of the second RAM memory 44, at the address received;

Otherwise:

the content of the control register is not loaded in the control register of the second RAM memory 44, and a flag with five bits is loaded at the address of the state register of the first RAM memory 42. This flag corresponds to acknowledgement of receipt obtained by a packet of five frames TX (ctr1000, ctr1001, ctr1010, ctr1011, ctr1100. If at least one of these five frames has an incorrect error detector code CRC, the flag is loaded at the address corresponding to this frame, and is transmitted to the control circuit 8, at the following transfer of the state register 000.

the control circuit receives the frame RX, and verifies whether the error detector code CRC RX is correct.

If this is the case:

the content of this register is loaded in the third RAM memory 62;

Otherwise:

a flag with five bits is loaded at the address of the state register of the first RAM memory 62. This flag is loaded when at least one error is detected in a packet with five frames RX.

A counter which is integrated in the central unit 50 of the control circuit 8 will be incremented or decremented according to the result of the above-described verification.

This counter will be incremented if at least one of the following propositions is true:

the bit 5 of the state address000 is “1”;

the error detector code CRC for at least one of the five frames is incorrect;

the address of the frame TX is not the same as that of the frame RX;

If the capacity of the counter is exceeded, an interrupt signal is transmitted to the central unit 50 of the control circuit 8. The latter can wait, or can interrupt the communication protocol. An interrupt is maintained for as long as a correct transfer of five frames has not been carried out, i.e. for as long as the line interface 6 is below the minimum supply threshold.

It is possible to mask the interrupt by an order programmed in the central unit 50. In this case, when the counter indicates 32 successive errors, the central unit 50 receives an alarm signal.

This occurs when the following propositions are true:

the capacity of the error counter is exceeded, and the interrupt is not masked;

the line interface 6 has detected a positive or negative alarm signal, and the interrupt is not masked;

the line interface 6 is not activated, owing to the fact that its supply voltage is lower than the predetermined threshold, and the interrupt is not masked.

The counter is previously initialized to a maximum value of 32.

1. A device (4) for connection of an apparatus on a telephone line, comprising a line interface (6) which is connected to the telephone line, and a control circuit (8) to control this line interface (6), which can detect a fault in transmission through the line, the line interface (6) and the control circuit (8) each comprising at least one memory (42, 44, 62,64), and being designed to exchange information via a galvanic connection, which device is characterized in that communication between the line interface (6) and the control circuit (8) is produced according to a protocol during which:
the control circuit (8) transmits continuously, and in a loop, to the line interface (6), a first data packet which is provided with a first address, and receives in return from the line interface (6) a second data packet, which is provided with a second address; and
the control circuit (8) detects a transmission fault on the line, if the first and second addresses are different.

2. A device as claimed in claim 1, characterized in that the first and second data packets comprise respectively the contents of a control register (106) and of a state register (114), as well as a memory address (104,112) associated with each register, the first data packet additionally comprising a synchronization key.

3. A device as claimed in claim 2, characterized in that the line interface (6) can detect the synchronization key, decode the memory address of each register, and return the content of the state register, provided with the same address, into the memory of the control circuit.

4. A device as claimed in claim 2, characterized in that the contents of each control register (106) and of each state register (114) are designed to be validated by an error detector code (108,116).

5. A device as claimed in any one of claims 1 to 4, characterized in that, before the connection is established between the line interface (6) and the control circuit (8), the latter transmits to the line interface (6) a specific binary frame, which makes it possible to initialize the exchange of data.

6. A device as claimed in any one of claims 1 to 5, characterized in that, if a fault occurs on the line, the line interface (6) returns to the control circuit (8) state data comprising at least one error indication bit.

7. A device as claimed in claim 6, characterized in that the control circuit (8) compares the address (104) of the control register (106) and the address (112) of the state register (114), in order to monitor the operation of the line interface (6).

8. A device as claimed in any one of claims 1 to 7, characterized in that the control circuit (8) is a micro-controller.

9. A device as claimed in claim 1, characterized in that the galvanic connection comprises three capacitors C1, C2 and C3.

10. A method for detection of a fault in a connection between an apparatus which is connected to a telephone line by means of a line interface (6) which is piloted by a control circuit (8), which method is characterized in that:
the control circuit transmits continuously, and in a loop, to the line interface (6), a first data packet which is provided with a first address, and receives in return from the line interface (6) a second data packet, which is provided with a second address; and
the control circuit (8) detects a transmission fault on the line, if the first and second addresses are different.

11. A method as claimed in claim 10, characterized in that the first and second data packets comprise respectively the contents of a control register (106) and of a state 30 register (114), as well as a memory address (104,112) associated with each register, the first data packet additionally comprising a synchronization key, the line interface (6) detects the synchronization key, decodes the memory address of each register, and returns the content of the state register, provided with the same address, into the memory of the control circuit (8).

12. A method as claimed in claim 11, characterized in that the contents of the control register and state registers are validated by an error detector code.

13. A method as claimed in claim 12, characterized in that, before the connection is established between the line interface (6) and the control circuit (8), the latter transmits to the line interface a specific binary frame, which makes it possible to initialize the exchange of data, and in that, if a fault occurs on the line, the line interface (6) returns to the control circuit (8) state data comprising at least one error indication bit.
